(19) United States
(12) Patent Application Publication
(10) Pub. No.: US 2015/0010718 A1
(43) Pub. Date: Jan. 8, 2015

(54) HEAT TRANSFER CONTROL IN PECVD SYSTEMS

(71) Applicant: TEL Solar AG, Trubbach (CH)

(72) Inventors: Stephan Jost, Azmoos (CH); Devendra Chaudhary, Jagatpura (IN); Markus Klindworth, Wangs (CH)

(21) Appl. No.: 14/368,386

(22) PCT Filed: Dec. 20, 2012
(86) PCT No.: PCT/EP2012/076434

§ 371 Date: Jun. 24, 2014

Related U.S. Application Data
(60) Provisional application No. 61/582,871, filed on Jan. 4, 2012.

(51) Int. Cl. C23C 16/44; C23C 16/513

(52) U.S. Cl. CPC C23C 16/4411; C23C 16/44; C23C 16/513
USPC 427/569; 427/248.1; 118/715

(57) ABSTRACT

The invention relates to a method for manufacturing thin films on substrates, the method comprising providing a deposition system, said system comprising an inner non-airtight enclosure for containing at least one substrate and an outer airtight chamber completely surrounding said enclosure, and providing at least one substrate in the inner non-airtight enclosure. The inner non-airtight enclosure is maintained at a pressure lower than the pressure within said outer airtight chamber, and a backfilling gas comprising at least hydrogen or helium is introduced into the outer airtight chamber volume.

### CROSS REFERENCE TO RELATED APPLICATIONS

This application is a 35 U.S.C. 371 National Phase Entry Application from PCT/EP2012/076434, filed Dec. 20, 2012, which claims the benefit of U.S. Provisional Application No. 61/582,871, filed Jan. 4, 2012, the disclosures of which are incorporated herein in their entirety by reference.

This invention relates to improvements in systems for depositing of thin films, especially thin silicon films with low contamination, by means of plasma enhanced chemical vapor deposition (PECVD). In more detail it refers to improvements of a deposition process used in a parallel-plate reactor known in the art.

### DEFINITIONS

Substrates in the sense of this invention are components, parts or work pieces to be treated in a processing apparatus. Substrates include but are not limited to flat, plate shaped parts having rectangular, square or circular shape.

CVD Chemical Vapour Deposition is a well-known technology allowing the deposition of layers on substrates. A usually liquid or gaseous precursor material is being fed to a process system where a reaction of said precursor results in deposition of said layer. LPCVD is a common term for low pressure CVD, and PECVD is a common term for plasma enhanced CVD.

A solar cell or photovoltaic cell (PV cell) is an electrical component capable of transforming light (essentially sun light) directly into electrical energy by means of the photoelectric effect.

A thin-film solar cell in a generic sense includes, on a supporting substrate, at least one p-i-n junction established by a thin film deposition of semiconductor compounds, sandwiched between two electrodes or electrode layers. A p-i-n junction or thin-film photoelectric conversion unit includes an intrinsic semiconductor compound layer sandwiched between a p-doped and an n-doped semiconductor compound layer. The term thin-film indicates that the layers mentioned are being deposited as thin layers or films by processes like, PEVCD, CVD, PVD or alike. Thin layers essentially mean layers with a thickness of 10 μm or less, especially less than 2 μm.

### BACKGROUND OF THE INVENTION

Device-grade semiconductor, especially silicon materials grown by low temperature PECVD typically employ deposition recipes with specific pressure (up to 10 mbar or 20 mbar) and depletion regimes (i.e. the majority of the silane fed to a reactor is actually consumed by the deposition process). Large scale homogeneity is ensured by using a proper isothermal reactor, with efficient showerhead gas distribution system for controlling both gas preheating and gas composition over the whole substrate area before it enters the plasma region. Contamination issues during deposition are attenuated by the inherent small gas leak between the actual deposition chamber, where the plasma is properly confined, and an outer surrounding vacuum chamber: this allows the establishment of a differential pressure during deposition, with a higher pressure inside the deposition chamber. This inner non-airtight enclosure in an outer airtight chamber arrangement is also known in the art as Plasmabox reactor.

FIG. 1 shows such an arrangement of a basic Plasmabox reactor. It shows an inner non-airtight enclosure 20 in which a prevailing pressure can be established lower than the atmospheric pressure. Means for creating a plasma zone affecting at least one substrate within said enclosure have been omitted. Such means include gas supplies to the reactor, RF energy supply to the reactor, and means for controlling the pressure of the reactor. An airtight chamber 10 surrounding said enclosure 20 is being kept, during operation, at a pressure lower than the pressure within said enclosure 20. A pumping line 30 acts as exhaust to both inner enclosure 20 and outer chamber 10. A butterfly vent 50 allows distributing the pumping effect between enclosures 20 and 10, such establishing the differential pressure between chamber 10 and enclosure 20. As an example, U.S. Pat. No. 4,989,543 describes a deposition system allowing for operation under differential pressure conditions. There a pressure of 10¹ Pa for the inner enclosure is suggested, whereas the outer chamber can be pumped down to approximately 10⁻⁴ to 10⁻⁵ Pa.

PECVD deposition processes used for photovoltaic devices usually require high RF power to deposit layers such as μc-Si layers with low contamination. The power however results in a considerable heat-up of the reactor and the substrate involved. Temperatures of more than 200° C. however are often detrimental for the material and electrical properties of the layers already deposited. In order to dissipate the thermal load away from the reactor and the substrate, an arrangement as shown in FIG. 2 is known for the Plasmabox-type of reactor.

Inner reactors 70, 71, 72 are arranged in the volume 75 of an outer chamber 76. The inner reactors 70, 71, 72 are connected via pumping lines 86 to a vacuum pump 84 in order to allow for process conditions as described above. Furthermore, a controllable reactor vent (not illustrated) may be disposed upstream of vacuum pump 84, between vacuum pump 84 and the inner reactors 70, 71, 72 to permit a greater degree of control over the pressure in the reactors independently of the gas flow rate. Gas inlets to said inner reactors as well as electrical equipment, and substrates are not shown. The volume 75 is being pumped by a pump 80. Vent 82 allows for controlling and adjusting the pressure difference between inner reactors 70, 71, 72 and outer volume 75. Vent 82 is not mandatory, but is beneficial to reduce gas consumption.

Each reactor 70, 71, 72 is cooled by cooling plates 60 arranged in close relationship to the reactor, e.g. above and below as shown in FIG. 2. Although three inner reactors 70, 71 and 72 are illustrated for simplicity, any number of inner reactors is possible: currently, 10 inner reactors is a common configuration. The heat transfer is accomplished by radiation and thermal conduction through the gas present in chamber 76's volume 75.

Usually during a deposition cycle working gases (like silane, hydrogen, inert gases, dopants, etc.) are being fed directly to reactors 70, 71 and 72, whereas volume 75 is being “backfilled” via inlet 88 with an inexpensive and inert gas. This backfilling was established in order to better remove the leaking gases from volume 75 by diluting the gases and increasing the flow towards the exhaust pump(s). The flow however was—during a deposition cycle—chosen so carefully that the pressure in volume 75 did not essentially increase. Thus, during a deposition cycle the volume 75 of chamber 76 exhibits purge gas (N₂) supplied at a minimal flow and deposition gases leaking out of the reactor. N₂ was chosen because it's non-toxic, inert and widely available. However, even though the pressure in volume 75 was controlled to be lower than the pressure in reactors 70-72, the purge gas cannot completely be prevented from entering inner reactors 70-72. This has turned out to be a problem since even traces of nitrogen incorporated in the absorber layer of a photovoltaic stack, i.e. the intrinsic silicon layer, deteriorate the properties of the photovoltaic element, especially in case of microcrystalline silicon. The obvious solution to replace nitrogen by another inert gas like argon is too costly.

Usually after each deposition cycle an automated cleaning cycle is applied by introducing e.g. fluorine or chlorine containing gas compounds into reactors 70-72. During plasma cleaning those reactors, the N₂ flow into volume 75 is increased until the pressure in the vacuum chamber 76 is slightly higher than in reactors 70-72. Thus the highly reactive (corrosive) gases can be prevented from entering the chamber 76. Since the deposition process is concentrated in reactors 70-72, the contamination of the surrounding chamber 76 is generally lower.

Increasing deposition rates in a system as described above always requires increasing the RF power fed to the reactors, which inevitably increases the need to reduce excessive heating of the equipment and the substrates treated. Further, the quality of the layers deposited (such as degree of crystallinity, thickness) also depends on substrate temperature. Insufficient cooling will thus lead to a heating-up of the substrate over the time of deposition and will therefore affect the layer properties. Further, thin film material for photovoltaic applications must have a very low contamination with oxygen, fluorine and nitrogen. A (inner) Plasmabox reactor is not 100% leak tight, small amounts of gases from the reactor can leak outside the reactor. However, due to diffusion gases from volume 75 will enter also into reactors 70-72 even if the reactor has a higher pressure than the surrounding vacuum chamber 76. In order to reduce the influence of diffusion, one could increase the differential pressure (e.g. lowering the pressure in volume 75 and/or increase pressure in reactors 70-72). This however has new disadvantages: Besides the fact, that any increase of pumping power is costly, the leak rate from the reactors to the outer chamber would increase (loss of working gases) which results in contamination of the outer chamber 76. Further, the leak flow is not homogeneous over the sealing area, in other words, depending on the chamber geometry, contamination, mechanical tolerances, certain areas will leak more than others. This leak flow pattern affects the layer homogeneity locally; it will likely copy such inhomogeneity as a flow pattern on the substrate, which will finally negatively affect the quality of the substrates treated. An increased pressure difference between reactors 70-72 and volume 75 of surrounding chamber 76 will worsen this problem.

Basically deposition regimes with higher pressures (up to 20 mbar or even up to 50 mbar) are desirable, since they normally result in a better quality of the silicon layers to be used in photovoltaics. However, in order to reduce the leakage to the outer chamber, the inner reactors should be sealed; however, seals capable of handling operation temperatures of up to 200° C. or up to 250° C. and having sufficient fluorine resistance are expensive.

### SUMMARY

This disclosure pertains to a method for manufacturing thin films on substrates, the method comprising providing a deposition system, this deposition system comprising an inner non-airtight enclosure, i.e. a reactor, for containing at least one substrate, and an outer airtight chamber completely surrounding the enclosure, and providing at least one substrate in the inner non-airtight enclosure. By “airtight” it should be understood that, under the intended working conditions and pressures, substantially no gas and/or air passes through the walls of the chamber, i.e. substantially no air or other gas may enter or leave the chamber. Likewise, by “non-airtight” it should be understood that it is possible that gas may pass through the walls of the enclosure under the intended working conditions and pressures, i.e. gas may possibly enter and/or leave the enclosure. The inner non-airtight enclosure is maintained at a pressure lower than or substantially equal to the pressure within the outer airtight chamber, and a backfilling gas comprising at least hydrogen or helium or even both is/are introduced into the outer airtight chamber volume. “Substantially equal pressure” means a pressure difference of <1 mbar, ideally <0.1 mbar. In consequence, contamination of the process environment within the inner non-airtight enclosure is reduced, since helium is chemically inert and hydrogen does not affect the majority of CVD deposition processes, and is indeed a commonly used component of CVD process gas. Since hydrogen and helium do not contaminate the processing environment in a negative manner, the outer chamber can be operated at substantially the same pressure or at overpressure with respect to the inner enclosure. This increase in pressure with respect to the prior art reduces the vacuum pumping requirement and also results in better heat transfer from the inner enclosure by conduction through the backfilling gas (heat conductivity is proportional to pressure at least for low pressures), and furthermore hydrogen and helium have a greater thermal conductivity than the nitrogen used in the prior art, further improving heat transfer. Thus simultaneously contamination of the processing environment is reduced, pumping power is reduced, and heat transfer from the inner enclosure is improved.

In an embodiment, the pressure difference between the inner non-airtight enclosure and the outer airtight chamber is established as being less than 1 mbar, particularly 0.05-1 mbar, more particularly 0.1 mbar. Alternatively, the pressure difference can be between 0.25-1 mbar, or more particularly 0.5 mbar.

In an embodiment, the inner non-airtight enclosure comprises a PECVD parallel plate reactor system, in which is established a pressure in the range of 0.3-50 mbar, particularly 2-40 mbar during deposition. Alternatively the range of 0.3-20 mbar is possible. Furthermore, RF power of between 200 W and 6 kW, particularly between 500 W and 6 kW is provided to the parallel plate reactor system for a 1.4 m² substrate, this RF power being scaled linearly for other substrate areas.

In an embodiment, the substrate is held at a temperature of between 150 and 250° C., particularly between 160 and 200° C., which is not detrimental for the material and electrical properties of layers deposited, and results in a less aggressive environment for any seals present, rendering sealing easier and less costly. In an embodiment, the thin films are silicon films, e.g. for producing semiconductor devices such as thin film solar cells. In an embodiment, heat is exchanged between the inner non-airtight enclosure and a plurality of cooling plates arranged above and below the inner non-airtight enclosure particularly within a distance of 1-100 mm, particularly 1-30 mm, further particularly 1-15 mm therefrom. Alternatively, this distance may be simply less than 3 mm, further particularly less than 1 mm, therefrom. This heat exchange occurs at least partially by conduction through the backfilling gas. This permits greater rate of cooling of the inner non-airtight enclosure. In an embodiment, at least one process gas comprising hydrogen is introduced into the inner non-airtight enclosure. Since the process gas includes hydrogen, hydrogen entry from the backfilling gas into the processing environment in the inner enclosure is reduced due to the partial pressure of hydrogen inside the inner enclosure, and in any case any hydrogen entering therein to will have no effect on the processing since the processing gas already incorporates hydrogen, therefore the process is by definition hydrogen compatible.

An object of the invention is likewise attained by a deposition system for manufacturing thin films on substrates. The system comprises an inner non-airtight enclosure, i.e. a reactor, for containing at least one substrate, and an outer airtight chamber completely surrounding the enclosure. The system further comprises a pressure difference maintenance arrangement adapted to maintain the inner non-airtight enclosure at a pressure lower than or substantially equal to the pressure within the outer airtight chamber, and the backfilling gas supply arrangement is adapted to supply backfilling gas comprising at least hydrogen or helium or even both into the outer airtight chamber, i.e. into the interior volume of the outer chamber. “Substantially equal pressure” means a pressure difference of <1 mbar, ideally <0.1 mbar.

As above, in consequence, contamination of the process environment within the inner non-airtight enclosure is reduced when the system is in operation, since helium is chemically inert, and since hydrogen does not affect the majority of CVD deposition processes and is indeed a commonly used component of CVD process gas. Since hydrogen and helium do not contaminate the processing environment in a negative manner, the outer chamber can be operated at overpressure with respect to the inner enclosure. This increase in pressure thus results in better heat transfer from the inner enclosure by conduction through the backfilling gas (heat conductivity is proportional to pressure at least for low pressures), and furthermore hydrogen and helium have a greater thermal conductivity than the nitrogen used in the prior art, further improving heat transfer. Thus simultaneously contamination of the processing environment is reduced and heat transfer from the inner enclosure is improved.

In an embodiment of the system, the system comprises a plurality of inner non-airtight enclosures, said plurality particularly being ten. Alternatively, other numbers are conceivable, such as three. This enables processing multiple substrates in different chambers simultaneously.

In an embodiment of the system, a plurality of cooling plates are arranged above and below the inner non-airtight enclosure or enclosures within a distance of 1-100 mm, particularly 15-20 mm, further particularly substantially 15 mm, therefrom. Alternatively the distance can be less than 3 mm, particularly less than 1 mm, therefrom. These cooling plates in close proximity to the inner enclosure or enclosures allow good heat transfer, and if the cooling plates are not attached to the inner enclosure or enclosures, permit easy removal and replacement of the enclosures.

In an embodiment of the system comprising multiple inner enclosures, the inner enclosures are arranged adjacent to each other, one cooling plate is arranged between adjacent inner enclosures, and one cooling plate is arranged on the outer side of each of the outermost inner non-airtight enclosures, i.e. one plate above the stack of inner enclosures, and one plate below the stack of inner enclosures, this permits good heat transfer for a stack of multiple inner enclosures.

In an alternative embodiment of the system, a plurality of cooling plates are provided attached to or integral with one side of each inner non-airtight enclosure. This allows greater heat transfer by conduction directly from the inner enclosure to its corresponding attached cooling plate. The gap between the upper surface of one inner non-airtight enclosure and an adjacent cooling plate attached to or integral with one side of an inner non-airtight enclosure may measure 30-100 mm, particularly 50-70 mm, further particularly substantially 60 mm. Additionally, a further cooling plate may be provided above the uppermost in a non-airtight enclosure, spaced therefrom by a distance of 1-100 mm, particularly 1-30 mm, further particularly 1-15 mm. Thus, heat can be transferred by conduction through the backfilling gas from the top of the inner reactors to the neighboring cooling plate.

In an embodiment of the system, the pressure difference maintenance means comprise a first vacuum pump in fluid connection with the inner non-airtight enclosure or with the plurality of inner non-airtight enclosures, particularly via a controllable reactor vent or valve, and a second vacuum pump in fluid connection with the outer airtight chamber via controllable vent.

Finally, an object of the invention is attained by the use of one of the above-mentioned methods for the manufacture of a thin-film solar cell.

### BRIEF DESCRIPTION OF THE FIGURES

The invention will now be described with reference to the following figures, which show:

FIG. 1: a reactor according to the prior art;

FIG. 2: a reactor with an arrangement of cooling plates; and

FIG. 3: a further reactor with an alternative arrangement of cooling plates.

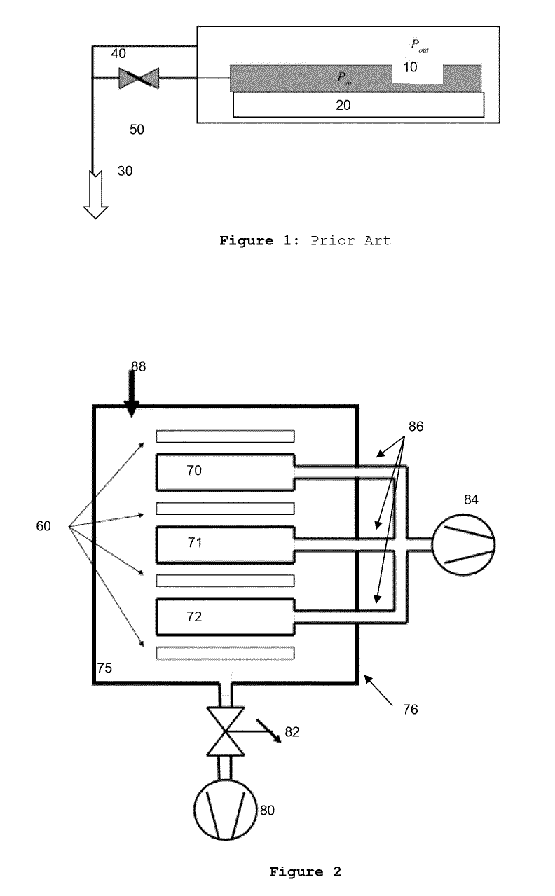

### DETAILED DESCRIPTION

According to the invention, the deposition process shall be modified as follows: During a deposition cycle H₂ gas is fed via inlet 88 into chamber 76 to increase the pressure in volume 75. The pressure can be controlled by the H₂ gas inflow and/or a control valve 82 in the pump line. Up to about 10 mbar pressure the heat conductance increases with increasing gas pressure, so for high RF power applied in reactors 70-72 such a high pressure regime is preferred. It is further proposed to arrange cooling plates 60 very close to the reactor, preferable having a distance in the range of less than 3 mm, preferably less than 1 mm. This close arrangement allows better heat transfer from the reactors 70-72 to cooling plates 60. By not fixedly mounting cooling plates 60 to reactors 70-72 it is still possible to quickly remove the reactors from a stack as shown in FIG. 2. Typically, the distance between the reactor bottom and the adjacent cooling plate is 15-20 mm.

As has been outlined above, the differential pressure regime as proposed by Prior Art is not sufficient for high deposition rates even when using an increased pressure difference. The use of H₂ or He according to the invention as backfilling gas for volume 75 in outer chamber 76 allows escaping that rule, since hydrogen is a common working gas in deposition processes for amorphous and microcrystalline silicon, and helium is chemically inert. In the case of hydrogen, diffusion is reduced (due to presence of hydrogen as well inside reactors 70-72 and outer volume 75) and the residual diffusion-enforced inflow of hydrogen is not critical. Thus the differential pressure can be reduced, which positively affects the flow regime inside the reactor: The leak flow will less effect the substrate to be treated. In a preferred embodiment a pressure difference (during a deposition cycle) between inner reactor(s) 70-72 and outer volume 75 is controlled to be 1 mbar or less, preferably 0.25 mbar-1 mbar, alternatively preferably 0.05 mbar-1 mbar, especially preferred 0.5 mbar or 0.1 mbar.

Moreover hydrogen has a far better heat conductivity (0.18 W/m/K @20° C.), as does helium (0.14 W/m/K @20° C.), compared to nitrogen (0.026 W/m/K @20° C.). Hydrogen can further be easily removed from the exhaust gases in a gas scrubber and is widely available in the semiconductor industry.

Two criteria have to be taken into account for the gas selection: the gas shall not contaminate the layer and shall have a good heat conductance. H₂ and He have excellent heat conductance. H₂ will not contaminate the layer, because H₂ in large quantities is used for thin film photovoltaic layers anyway. Inert gases especially in low quantities can be accepted inside the reactor.

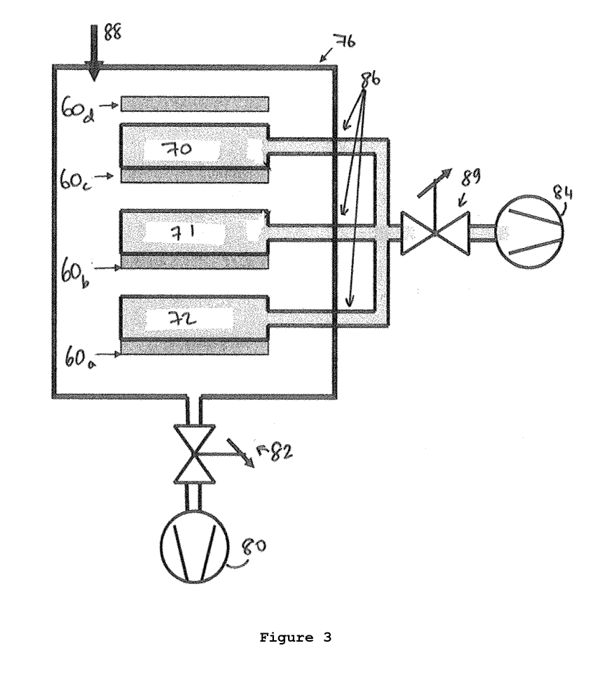

FIG. 3 illustrates schematically a variation of a reactor 76 similar to that of FIG. 2, comprising an alternative arrangement of cooling plates. The arrangement of FIG. 3 differs from that of FIG. 2 in that a reactor valve or vent 89 is provided disposed between vacuum pump 84 and pumping lines 86 leading from reactors 70, 71, 72. Furthermore, in this embodiment, three of the four illustrated cooling plates 60a, 60b, 60c are attached to, or are integral with, the underside of each reactor 72, 71, 70 respectively, and the distance from the top of each reactor to the underside of the adjacent cooling plate is 30-100 mm, particularly 50-70 mm, further particularly substantially 60 mm, although of course any particular distance as possible. Above the uppermost reactor 70, cooling plate 60d is provided similarly to the arrangement of FIG. 2, separated therefrom by 1-100 mm, particularly 1-30 mm, further particularly 1-15 mm therefrom. Of course, other separation distances are possible. For different numbers of reactors, each reactor comprises a cooling plate on its underside. As an alternative to cooling plates 60a, 60b, 60c, the bottom of each reactor 70, 71, 72 is directly cooled.

A method for manufacturing thin films in a deposition system is being addressed, wherein said system comprises an inner non-airtight enclosure for containing at least one substrate, an outer airtight chamber completely surrounding said enclosure. During regular operation said inner chamber is being kept at a pressure lower than or substantially equal to the pressure within said outer enclosure. A backfilling gas comprising at least hydrogen or helium is introduced into the outer chamber volume. Preferably a pressure difference of less than 1 mbar between inner non-airtight enclosure and outer airtight chamber is being established.

The invention is especially useful for the deposition of silicon in a PECVD parallel plate reactor system using a pressure range between 0.3-50 mbar, or 0.3-20 mbar during deposition and RF power between 200 W and 6 kw, particularly 500 W and 6 kW (relative to a 1.4 m² substrate). The substrate is being held at a temperature between 150-250° C., particularly 160-200° C. The inventive method allows depositing silicon layers with very low contamination. The inventive method can be used without hardware modifications in existing PECVD deposition systems with a Plasmabox reactor using a pressure differential process like an Oerlikon Solar KAI system. Especially the disadvantages of elaborate sealing and increased pumping power can be avoided.

Although the invention has been described above in reference to specific embodiments, variations therefrom are possible within the scope of the invention as defined in the appended claims.

1. Method for manufacturing thin films on substrates, the method comprising:
providing a deposition system, said system comprising an inner non-airtight enclosure for containing at least one substrate and an outer airtight chamber completely surrounding said enclosure, and providing at least one substrate in the inner non-airtight enclosure,
maintaining said inner non-airtight enclosure at a pressure lower than or substantially equal to the pressure within said outer airtight chamber,
introducing a backfilling gas comprising at least hydrogen or helium into the outer airtight chamber volume.

2. Method according to claim 1, wherein a pressure difference between the inner non-airtight enclosure and the outer airtight chamber of less than 1 mbar, particularly 0.05-1 mbar, further particularly 0.1 mbar is established.

3. Method according to one of claim 1 or 2, wherein the inner non-airtight enclosure comprises a PECVD parallel plate reactor system, a pressure in the range 0.3-50 mbar, particularly 2-40 mbar or 0.3-20 mbar being established in the inner non-airtight enclosure during deposition and RF power between 500 W and 6 kW is provided to the parallel plate reactor system in the case of a 1.4 m² substrate, the RF power being scaled linearly for other substrate areas.

4. Method according to one of claims 1-3, wherein the substrate is held at a temperature of between 150-250° C., particularly 160-200° C.

5. Method according to one of claims 1-4, wherein said thin films are silicon films.

6. Method according to one of claims 1-5, comprising heat exchange between the inner non-airtight enclosure and a plurality of cooling plates arranged above and below said inner non-airtight enclosure particularly within a distance of 1-100 mm, particularly 1-30 mm, further particularly 1-15 mm, therefrom, said heat exchange occurring at least partially by conduction through the backfilling gas.

7. Method according to one of claims 1-6, comprising introducing at least one process gas comprising hydrogen into the inner non-airtight enclosure.

8. Deposition system for manufacturing thin films on substrates, said system comprising:
an inner non-airtight enclosure for containing at least one substrate;
an outer airtight chamber completely surrounding said enclosure;
a pressure difference maintenance arrangement adapted to maintain said inner non-airtight enclosure at a pressure lower than the pressure within said outer airtight chamber;
a backfilling gas supply arrangement adapted to supply a backfilling gas comprising at least hydrogen or helium into the outer airtight chamber volume.

9. System according to claim 8, wherein the system comprises a plurality of said inner non-airtight enclosures, said plurality particularly being ten.

10. System according to one of claim 8 or 9, comprising a plurality of cooling plates arranged above and below each inner non-airtight enclosure within a distance of 1-100 mm, particularly 1-30 mm, further particularly 1-15 mm.

11. System according to claims 9 and 10, wherein the inner non-airtight enclosures are arranged mutually adjacent, and wherein one cooling plate is arranged between adjacent inner non-airtight enclosures, and one cooling plate is arranged on the outer side of each of the outermost inner non-airtight enclosures.

12. System according to one of claim 8 or 9, comprising a plurality of cooling plates attached to or integral with one side of each inner non-airtight enclosure.

13. System according to claim 12, wherein a gap between an upper surface of one inner non-airtight enclosure and an adjacent cooling plate attached to or integral with one side of an inner non-airtight enclosure measures 30-100 mm, particularly 50-70 mm, further particularly substantially 60 mm.

14. System according to one of claim 12 or 13, wherein a further cooling plate is provided above the uppermost in a non-airtight enclosure, spaced therefrom by a distance of 1-100 mm, particularly 1-30 mm, further particularly 1-15 mm.

15. System according to one of claims 8-14, wherein the pressure difference maintenance means comprise a first vacuum pump in fluid connection with the inner non-airtight enclosure or with the plurality of inner non-airtight enclosures, and a second vacuum pump in fluid connection with the outer airtight chamber via a controllable vent.

16. System according to claim 15, wherein the first vacuum pump is in fluid connection with the inner non-airtight enclosure or with the plurality of inner non-airtight enclosures via a controllable reactor vent.

17. Use of the method of one of claims 1-7 for the manufacture of a thin-film solar cell.
